(19) United States
(12) Patent Application Publication
(10) Pub. No.: US 2010/0025697 A1
(43) Pub. Date: Feb. 4, 2010

(54) OPTICAL MODULE

(75) Inventor: Atsushi KAWAMURA, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: MITSUBISHI ELECTRIC CORPORATION, Chiyoda-ku (JP)

(21) Appl. No.: 12/575,512

(22) Filed: Oct. 8, 2009

Related U.S. Application Data
(62) Division of application No. 11/933,749, filed on Nov. 1, 2007.

(30) Foreign Application Priority Data
Feb. 27, 2007 (JP) 2007-047844

(51) Int. Cl. H01L 33/00

(52) U.S. Cl. 257/81; 257/E33.066

(57) ABSTRACT

An optical module of the present invention includes a semiconductor device, a grounded metal member for mounting the semiconductor device thereon, a substrate for mounting the grounded metal member thereon, and a lead pin fixed to and insulated from the grounded metal member and soldered to the substrate. The lead pin is used to supply power to the semiconductor device. The grounded metal member has a protrusion on a surface thereof facing the substrate and wherein the protrusion of the grounded metal member is in contact with the substrate.

### CROSS-REFERENCE TO RELATED APPLICATION

This application is a divisional application of U.S. application Ser. No. 11/933,749, filed Nov. 1, 2007, the entirety of which is incorporated herein by reference, which claims the priority of Japanese Patent Application No. 2007-047844, filed Feb. 27, 2007.

### BACKGROUND OF THE INVENTION

1. Field of the Invention

The present invention relates to optical modules, and more particularly to optical modules suitable for mounting on a substrate.

2. Background Art

JP-A-2004-264659 discloses an optical transceiver module which is a hermetically sealed package containing a light emitting device and a photodetector. Since such an optical module includes lead pins to supply power to the semiconductor devices therein, the module can be fixedly mounted onto a substrate by soldering these lead pins to the substrate. In this case, however, the lead pins must be electrically isolated from the stem (a metal member) on which the semiconductor devices are mounted, in order to prevent shorting. (Other prior art includes JP-A-2006-41083, JP-A-2003-282631, and JP-A-11-110774 (1999)).

Thus, conventional optical modules are often mounted onto a substrate by soldering the power supply lead pins for their devices to the substrate. However, it has happened that such soldering has caused shorting between these lead pins and the metal member on which the devices are mounted, preventing electrical signals from passing through the lead pins.

The present invention has been devised to solve the above problems. It is, therefore, an object of the present invention to provide an optical module constructed to prevent shorting between its lead pins and stem due to solder creep when these lead pins are soldered to a substrate.

### SUMMARY OF THE INVENTION

Thus, the prevent invention provides an optical module constructed to prevent shorting between its lead pins and stem due to solder creep when these lead pins are soldered to a substrate. The features and advantages of the present invention may be summarized as follows.

According to one aspect of the present invention, an optical module include one or more semiconductor devices, a grounded metal member for mounting the one or more semiconductor devices thereon, a substrate for mounting the grounded metal member thereon, and one or more lead pins fixed to and insulated from the grounded metal member and soldered to the substrate, the one or more lead pins being used to supply power to the one or more semiconductor devices, wherein the grounded metal member has a protrusion on a surface thereof facing the substrate, and wherein the protrusion of the grounded metal member is in contact with the substrate.

Other and further objects, features and advantages of the invention will appear more fully from the following description.

### BRIEF DESCRIPTION OF THE DRAWINGS

FIG. 1A is an elevational view of the optical module, and

FIG. 1B is a bottom view of the stem of the optical module according to a first embodiment of the present invention;

FIG. 2A is an elevational view of the optical module, and FIG. 2B is a bottom view of the stem of the optical module according to a second embodiment of the present invention;

FIG. 3 shows how the diameter of the GND lead pin affects the heat dissipation characteristics of the optical module; and

FIG. 4A is an elevational view of the optical module, and FIG. 4B is a bottom view of the stem of the optical module according to a third embodiment of the present invention.

### DETAILED DESCRIPTION OF THE PREFERRED EMBODIMENTS

### First Embodiment

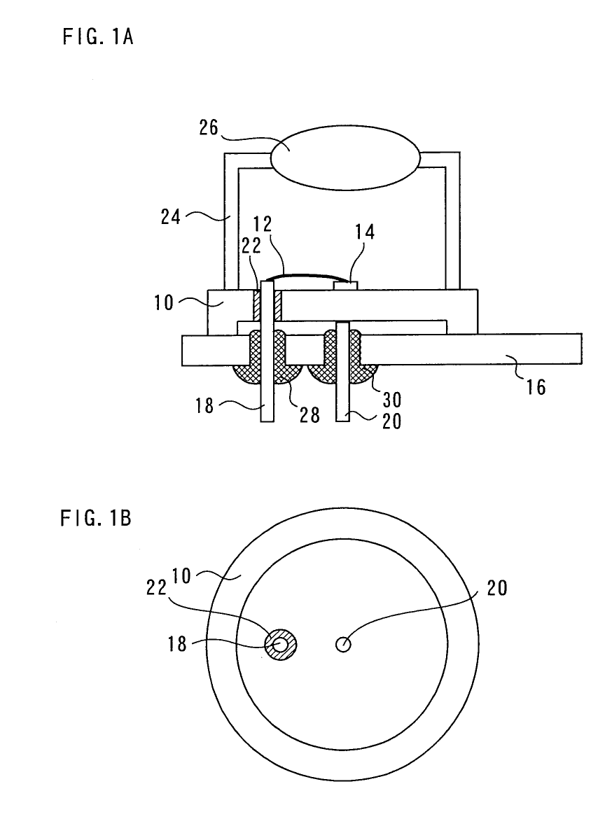

FIGS. 1A and 1B are diagrams illustrating an optical module mounted on a substrate 16 according to a first embodiment of the present invention. Specifically, FIG. 1A is an elevational view of the optical module, and FIG. 1B is a bottom view of the stem 10 of the optical module. The stem 10 is a metal member having a circular plate-like shape. It has an annular protrusion along its circumference (see FIG. 1B) and on its surface facing the substrate 16 (see FIG. 1A). The stem 10 also has two holes for passing a lead pin 18 and a GND lead pin 20 therethrough, respectively. A light emitting device 14 is mounted on the stem 10 (having a shape as described above) and is connected to the lead pin 18 by a gold wire 12. The light emitting device 14 is driven by an electrical signal from the lead pin 18. The lead pin 18 is insulated and fixed in one of the holes of the stem 10 by a glass sealant 22. Further, a GND lead pin 20 is welded in the other hole of the stem 10. Therefore, the GND lead pin 20 and the stem 10 are at the same potential. It should be noted that the stem 10 has a cap 24 welded thereto, and a lens 26 is mounted in the cap 24 to collimate light emitted from the light emitting device 14. The light emitting device 14 is enclosed and hermetically sealed by the cap 24, the lens 26, and the stem 10.

The optical module of the present embodiment, configured as described above, is mounted on the substrate 16. The substrate 16 has holes for receiving the lead pin 18 and the GND lead pin 20 of the optical module. The optical module is fixedly mounted onto the substrate 16 by inserting the lead pin 18 and the GND lead pin 20 into the above receiving holes and soldering these lead pins to the substrate 16 with solder 28 and 30, respectively. At that time, the GND lead pin 20 is soldered to a pattern on the substrate 16 held at ground potential (hereinafter referred to as a “grounding pattern”). Since the substrate 10 and the GND lead pin 20 are at the same potential (as described above), the stem 10 is grounded through the GND lead pin 20, that is, the stem 10 is a grounded metal member. Further, the stem 10 is mounted onto the substrate 16 such that its protrusion is in contact with the substrate 16, as shown in FIG. 1A. According to the present embodiment, the grounding pattern extends over the portion of the substrate 16 in contact with the stem 10. That is, both the GND lead pin 20 and the protrusion of the stem 10 are in contact with the grounding pattern on the substrate 16.

It is common that an optical module is fixedly mounted onto a substrate by soldering the power and ground lead pins for its device(s) to the substrate. This soldering must be done so as to avoid shorting between these lead pins and the stem to allow the lead pins to carry electrical signals without any problem. However, during the soldering process, the molten solder may creep up the lead pins and come into contact with the stem. This will prevent electrical signals from passing through the lead pins. In order to prevent such shorting, the optical module may be soldered to the substrate in such a way that they are sufficiently spaced from each other, that is, they are spaced a distance greater than the distance the solder creeps up the lead pins (hereinafter referred to as the “solder creep-up distance”). This, however, requires accurate adjustment of the distance between the stem and the substrate, which is generally difficult to achieve.

According to the present embodiment as described above, the stem 10 has a protrusion on the surface thereof facing the substrate 16, and the optical module is mounted on the substrate 16 such that the protrusion of the stem 10 is in contact with the substrate 16. Therefore, the distance between the stem and the substrate is determined by the protruding dimension of the protrusion of the stem. According to the present embodiment, this dimension is greater than the “solder creep-up distance” (i.e., the distance the solder creeps up the lead pins), preventing shorting between the lead pins and the stem.

Further, the above protrusion of the stem 10 provided in accordance with the present embodiment also has other beneficial effects such as enhanced stem grounding, reduced “external crosstalk,” and reduced thermal resistance (or enhanced heat dissipation), as described below. The stem grounding enhancing effect of the protrusion will be first described. The stem 10 is a metal member and must be grounded to prevent degradation of the high frequency characteristics of the light emitting device 14 mounted thereon. That is, the grounding of the stem 10 is essential to enable full functioning of the optical module. A common method for grounding the stem 10 is to weld the GND lead pin to the stem (thereby electrically coupling them together) and then solder the GND lead pin to the grounding pattern on the substrate. However, in order to reduce the required mounting space of the optical module, it may be necessary to reduce the diameter of the GND lead pin, which results in an increase in the resistance of the GND lead pin. This may result in a potential difference between the stem and the grounding pattern on the substrate and hence in unstable potential of the stem, which may degrade the high frequency characteristics of the optical module.

On the other hand, since the stem 10 of the present embodiment has a protrusion in contact with the grounding pattern on the substrate 16 (as described above), the stem 10 is electrically connected to the grounding pattern on the substrate 16 through this protrusion as well as through the GND lead pin 20, which reduces the resistance between the stem 10 and the grounding pattern on the substrate 16 and hence enhances the grounding of the stem 10. This prevents degradation of the high frequency characteristics of the optical module.

The “external crosstalk” reducing effect of the protrusion of the stem 10 will now be described. The term “external crosstalk,” as used herein, refers to interference of electromagnetic waves from one optical module with an electrical signal in another optical module. An example of such external crosstalk is interference of electromagnetic waves emitted from one optical module with the electrical signal passing through a lead pin in another optical module. However, the stem 10 of the present embodiment (having a protrusion) covers the portion of the lead pin 18 extending from the substrate 16 to the stem 10, preventing this lead pin portion from being significantly affected by electromagnetic waves from other optical modules. Thus, the present embodiment allows a reduction in external crosstalk of an optical module. Further, since the above lead pin portion is covered with the protrusion of the stem 10 (as described above), the optical module of the present embodiment exhibits a reduction in unwanted field emission.

The thermal resistance reducing effect (or heat dissipation enhancing effect) of the protrusion of the stem 10 will now be described. The heat dissipation within the optical module is primarily determined by the heat dissipation capacity of the stem 10. The stem 10 dissipates heat both through its surfaces and through the GND lead pin coupled to the grounding pattern on the substrate. Further, the protrusion of the stem 10 (of the present embodiment) allows the stem to dissipate an increased amount of heat through its surfaces. Furthermore, since the protrusion of the stem 10 is in contact with the grounding pattern on the substrate 16, the stem 10 has reduced thermal resistance (or enhanced heat dissipation characteristics), as compared to when only the GND lead pin 20 is in contact with the grounding pattern on the substrate. This thermal resistance reducing effect (or heat dissipation enhancing effect) of the protrusion of the stem 10 is especially useful to compensate for the increase in the thermal resistance of the GND lead pin 20 that occurs when the diameter of the lead pin is reduced to reduce the required mounting space of the optical module. Thus, the optical module of the present embodiment has improved heat dissipation characteristics.

The stem 10 of the present embodiment has an annular protrusion along its circumference and on its surface facing the substrate 16, as described above. However, the present invention is not limited to such a stem configuration. A protrusion of any shape may be formed on the surface of the stem facing the substrate 16 if such a protrusion prevents shorting between the lead pins and the stem due to solder creep when these lead pins are soldered to the substrate. Also in this case, the grounding pattern may be formed to extend over the portion of the substrate to be in contact with the protrusion of the stem to provide the stem grounding enhancing effect and the heat dissipation enhancing effect as described above.

Although in the optical module of the present embodiment the light emitting device 14 is mounted on the stem 10, the present invention is not limited to this particular semiconductor device. Any semiconductor device adapted to receive power through a lead pin(s) can be mounted on the stem, with the same effects.

### Second Embodiment

A second embodiment of the present invention provides another optical module having improved heat dissipation characteristics.

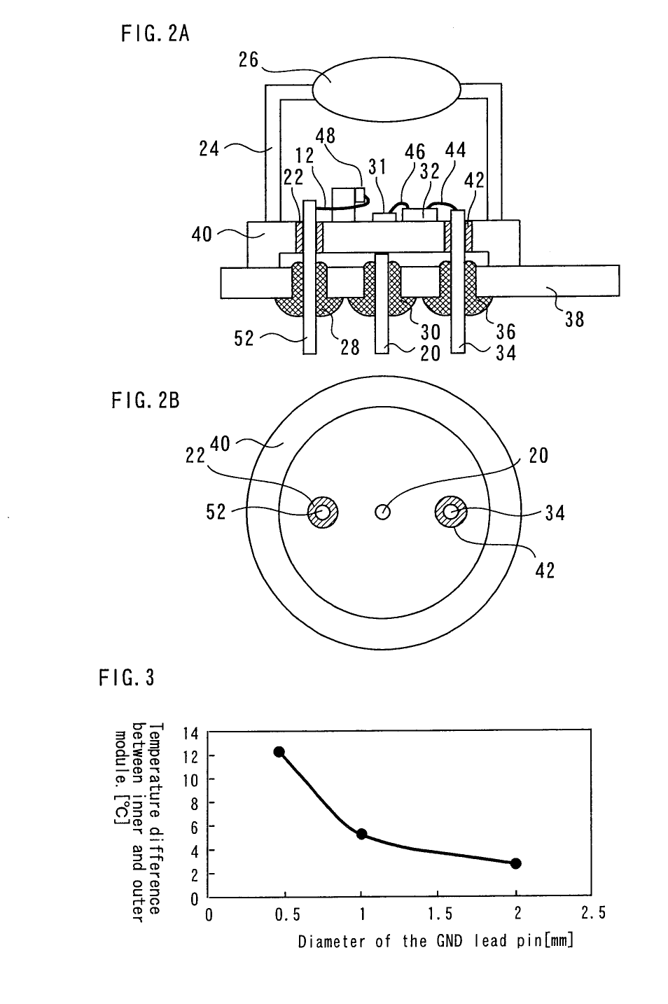

FIGS. 2A and 2B are diagrams illustrating the configuration of the optical module of the present embodiment. Specifically, FIG. 2A is an elevational view of the optical module, and FIG. 2B is a bottom view of the stem 40 of the optical module. In the optical module of the first embodiment, only the light emitting device 14 is mounted on the stem, whereas in the optical module of the present embodiment, a light emitting device 48, a photodetector 31, and an amplifier device 32, which amplifies the signal from the photodetector 31, are mounted on the stem. The stem 40 is similar in shape to the stem 10 of the first embodiment except that it has three holes instead of two. These three holes are used to fix a transmit side lead pin 52, a GND lead pin 20, and a receive side lead pin 34, respectively. As shown in FIG. 2B, the transmit side lead pin 52 is fixed to and insulated from the stem 40 by a glass sealant 22, and the receive side lead pin 34 is fixed to and insulated from the stem 40 by a glass sealant 42. The GND lead pin 20 is fixed to the stem 40 by welding. Further, as shown in FIG. 2A, the transmit side lead pin 52 is connected to the light emitting device 48 by a gold wire 12, the photodetector 31 is connected to the amplifier device 32 by a gold wire 46, and the amplifier device 32 is connected to the receive side lead pin 34 by a gold wire 44. A cap 24 with a lens 26 is mounted on the stem 40, as in the first embodiment.

The optical module of the present embodiment, configured as described above, is mounted on a substrate 38. The substrate 38 has holes for receiving the transmit side lead pin 52, the GND lead pin 20, and the receive side lead pin 34 of the optical module. The optical module is fixedly mounted onto the substrate 38 by inserting the transmit side lead pin 52, the GND lead pin 20, and the receive side lead pin 34 into these receiving holes and soldering these lead pins to the substrate 38 with solder 28, 30, and 36. At that time, the stem 40 is mounted onto the substrate 38 such that its protrusion is in contact with the substrate 38. More specifically, the protrusion of the stem 40 is in contact with the grounding pattern on the substrate 38, as in the first embodiment.

Since the photodetector usually receives a weak signal, it is often disposed adjacent an amplifier device provided to amplify that weak signal. It should be noted that the amplifier device consumes greater power than the photodetector and hence acts as a heat source. Therefore, it is important to improve the heat dissipation characteristics of such optical modules which contain a photodetector and hence an amplifier device. The stem 40 dissipates heat (partially) through the GND lead pin. FIG. 3 shows how the diameter of the GND lead pin affects the heat dissipation characteristics of the optical module. This relation was determined by a finite element method. Specifically, in FIG. 3, the vertical axis represents the difference between the internal temperature of the optical module and the external ambient temperature. As shown in FIG. 3, when the diameter of the GND lead pin is 0.45 mm, the internal temperature of the optical module is 10° C. or higher than the external ambient temperature. That is, in the case of an optical module containing a device that generates a large amount of heat and hence acts as a heat source (such as an amplifier device), it is important to enhance the heat dissipation characteristics of the optical module.

In the optical module of the present embodiment, both the GND lead pin 20 and the protrusion of the stem 40 are in contact with the grounding pattern on the substrate 38. This arrangement provides an increased contact area between the optical module and the substrate, as compared to when only the GND lead pin is in contact with the grounding pattern on the substrate, resulting in reduced heat resistance (or enhanced heat dissipation). Furthermore, since the stem has the above protrusion, it has an increased surface area, also resulting in increased heat dissipation. Thus, the present embodiment allows an optical module to have improved heat dissipation characteristics even if it contains an amplifier device.

### Third Embodiment

A third embodiment of the present invention provides an optical module adapted to reduce crosstalk between its light emitting device and photodetector.

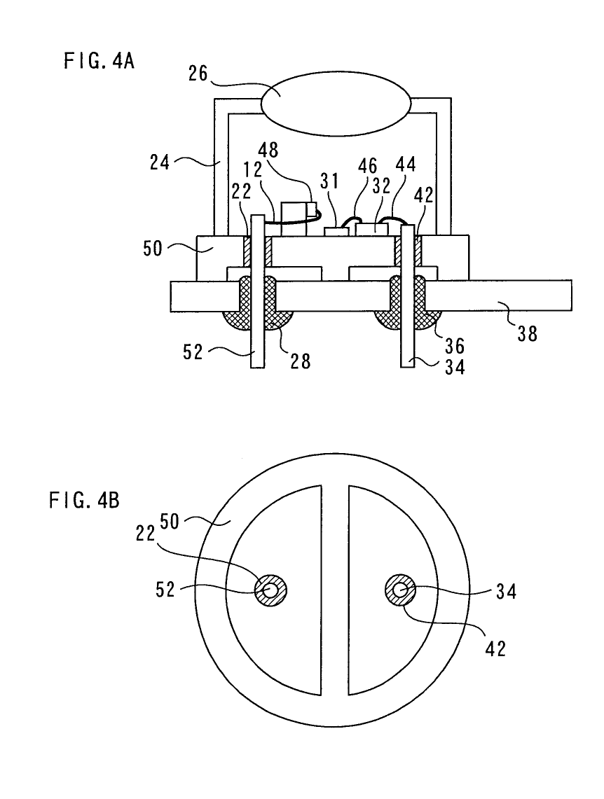

FIGS. 4A and 4B are diagrams illustrating an optical module mounted on a substrate according to the present embodiment. Specifically, FIG. 4A is an elevational view of the optical module, and FIG. 4B is a bottom view of the stem 50 of the optical module. The optical module of the present embodiment is similar to that of the second embodiment except that it does not include a GND lead pin and its stem has a different shape. The stem 50 and the substrate 38 each have two holes, instead of three, since this optical module does not include a GND lead pin (as described above). Further, in addition to an annular protrusion as shown in FIG. 2B, the stem 50 of the present embodiment has a protrusion that is disposed between a light emitting side lead pin 52 and a photodetector side lead pin 34 to separate these lead pins from each other. (This protrusion is hereinafter referred to as a “separating protrusion.”) The separating protrusion is coupled to the annular protrusion to form a single protrusion structure, as shown in FIG. 4B. That is, the light emitting side lead pin 52 and the photodetector side lead pin 34 are enclosed within their respective separate enclosures formed by the above protrusion structure (see FIG. 4B). It should be noted that the substrate 38 has a grounding pattern on the portion thereof in contact with the stem 50. Therefore, the stem 50 is a grounded metal member.

In an optical module, the electrical signal passing through the transmit side lead pin has higher intensity than that passing through the receive side lead pin. Their power ratio is 30 dB or higher. Therefore, in the case of an optical module containing both a light emitting device and a photodetector, the transmit side signal may interfere with the receive side signal and thereby cause noise in the receive side signal. This interference is hereinafter referred to as “internal crosstalk.” An example of such internal crosstalk is interference of unwanted electromagnetic waves emitted from the transmit side lead pin with the electrical signal passing through the receive side lead pin.

As described above, the stem 50 of the present embodiment forms two separate enclosures which respectively cover the portion of the substrate 38 surrounding the transmit side lead pin 52 (hereinafter referred to as the “transmit side lead pin portion”) and the portion of the substrate 38 surrounding the receive side lead pin 34 (hereinafter referred to as the “receive side lead pin portion”). That is, since the stem 50 is a grounded metal member (as described above), the transmit side lead pin portion and the receive side lead pin portion are enclosed within their respective grounded metal enclosures. This arrangement prevents the receive side lead pin portion from being significantly affected by unwanted electromagnetic waves emitted from the transmit side lead pin portion, resulting in reduced internal crosstalk. Further, it is also possible to reduce the external crosstalk described above, since the receive side lead pin portion is covered with a grounded metal member (i.e., the stem 50).

Although the protrusion structure of the stem of the present embodiment is made up of an annular protrusion and a separating protrusion (as described above), the present invention is not limited to this particular protrusion structure. The stem may have any protrusion structure that encloses the transmit side lead pin portion and the receive side lead pin portion, separately, with the same effect.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2007-047844, filed on Feb. 27, 2007 including specification, claims, drawings and summary, on which the Convention priority of the present application is based, are incorporated herein by reference in its entirety.

1. An optical module comprising:
one or more semiconductor devices;
a grounded metal member for mounting said one or more semiconductor devices thereon;
a substrate for mounting said grounded metal member thereon; and
one or more lead pins fixed to and insulated from said grounded metal member and soldered to said substrate, said one or more lead pins being used to supply power to said one or more semiconductor devices,
wherein said one or more semiconductor devices include a light emitting device and a photodetector,
wherein said grounded metal member has a protrusion on a surface thereof facing said substrate,
wherein said one or more lead pins include a transmit side lead pin for carrying an electrical signal to said light emitting device and a receive side lead pin for carrying an electrical signal to said photodetector,
wherein said protrusion of said grounded metal member is in contact with said substrate, and
wherein said protrusion of said grounded metal member includes two separate portions which respectively surround said transmit side lead pin and said receive side lead pin.
